(19) United States
(12) Patent Application Publication
(10) Pub. No.: US 2026/0118411 A1
(43) Pub. Date: Apr. 30, 2026

(54) TEMPERATURE CONTROL DEVICE AND TEMPERATURE CONTROL SYSTEM FOR PROVIDING TEMPERATURE CONTROL SPACE FOR INDIVIDUAL SEMICONDUCTOR PRODUCT IN TEST OF SEMICONDUCTOR PRODUCT

(71) Applicant: ATECO INC., Gunpo-si (KR)

(72) Inventors: Taek Seon LEE, Hwaseong-si (KR); Ho Nam KIM, Seongnam-si (KR); Sung Chul MOON, Gunpo-si (KR); Ki Sung KIM, Ansan-si (KR); Se I Mi CHOI, Anyang-si (KR)

(21) Appl. No.: 19/057,716

(22) Filed: Feb. 19, 2025

(30) Foreign Application Priority Data
Oct. 24, 2024 (KR) 10-2024-0146952

(51) Int. Cl. G01R 31/28

(52) U.S. Cl. CPC G01R 31/2874; G01R 31/2868

(57) ABSTRACT

According to one embodiment of the present disclosure, a temperature control system for providing a temperature control space for an individual semiconductor product in a test of a semiconductor product includes an insert configured to load the semiconductor product into an accommodating space with open one surface, a test tray on which a plurality of the inserts are loaded, a tester configured to test the semiconductor product through the insert in a state where the test tray is mounted, and a temperature control device in close contact with one surface of the test tray or the insert in a state where the test tray is mounted on the tester and configured to separate the accommodating space from an external space and control temperature of the accommodating space.

### CROSS-REFERENCE TO RELATED APPLICATION

This application claims the benefit of and priority to Korean Patent Application No. 10-2024-0146952, filed on Oct. 24, 2024, the entire disclosure(s) of which is hereby incorporated herein by reference in its entirety.

### BACKGROUND

### Field

The present disclosure relates to a temperature control device and a temperature control system for providing a temperature control space for an individual semiconductor product in a test of a semiconductor product.

### Description of Related Art

The background of the birth of a High Bandwidth Memory (HBM) is mainly derived from the demand for increased memory bandwidth in high-performance applications such as computers and graphics processing units. The existing Graphics Double Data Rate (GDDR) memory technology is widely used in high-performance graphics cards and systems, but the technology has reached the limit due to the increase in bandwidth demand. Therefore, memory manufacturers need a new technology that can provide higher bandwidth and process data more efficiently.

To meet these needs, the HBM has adopted an innovative design that forms a memory chip stack. The HBM can achieve high bandwidth by using vertically stacked memory chips, and can provide the advantage of reducing power consumption while taking up less space. These characteristics have become the background for the HBM to attract attention as the importance of memory bandwidth and power efficiency in high-performance computing and graphics processing systems increases.

Meanwhile, considering the efficiency aspect of test, the HBM requires testing in a die state before packaging. The HBM die has a much larger number of contacts than conventional memory due to the structure, and has the characteristic of having many contacts in a limited area with a fine pitch.

Many contacts of the HBM require high precision for electrical connection with the socket terminals of the tester, and a lot of heat is generated due to integration, making it difficult to maintain a constant test environment.

### SUMMARY

An object of the present disclosure is to provide a temperature control device and a temperature control system for a High Bandwidth Memory (HBM) or similar micro-sized semiconductor products.

Objects of the present disclosure are not limited to the above-described object, and other objects not mentioned will be clearly understood by those skilled in the art from the description below.

According to one embodiment of the present disclosure to achieve the object, a temperature control system for providing a temperature control space for an individual semiconductor product in a test of a semiconductor product, includes: an insert configured to load the semiconductor product into an accommodating space with open one surface; a test tray on which a plurality of the inserts are loaded; a tester configured to test the semiconductor product through the insert in a state where the test tray is mounted; and a temperature control device in close contact with one surface of the test tray or the insert in a state where the test tray is mounted on the tester and configured to separate the accommodating space from an external space and control temperature of the accommodating space.

The temperature control device may include a packing block in close contact with the test tray or the insert and formed with a discharge port for discharging a temperature-controlled test gas into the accommodating space and an exhaust port for exhausting the test gas from the accommodating space to the outside.

The temperature control device may further include an auxiliary fluid discharge pipe disposed to penetrate the packing block and configured to discharge an auxiliary fluid for temperature control into the accommodating space.

The temperature control device may further include a gas circulator configured to circulate the test gas and control temperature, and a duct block configured to distribute and deliver the test gas delivered from the gas circulator to a plurality of the packing blocks and deliver the test gas exhausted through the plurality of the packing blocks to the gas circulator.

The temperature control device may further include a temperature measurement sensor built into the packing block or the duct block to measure temperature.

The temperature control device may further include a distribution plate that forms a circulation path of the test gas between the plurality of duct blocks and the gas circulator.

One surface of the distribution plate facing the test tray may be formed to have an extent corresponding to the test tray, and each of the duct blocks may be disposed on one surface of the distribution plate to correspond to a different area of the test tray.

The temperature control device may further include a heat exchange unit disposed in the duct block and configured to control the temperature of the test gas distributed to the plurality of packing blocks.

The temperature control device may further include a circulation chamber in which the gas circulator is disposed and which provides a space in which the test gas is circulated, so that the test gas waits in a temperature-controlled state.

The temperature control device may further include a dry chamber that the circulation chamber is disposed inside and which maintains temperature of an internal space within a predetermined range.

The temperature control device may further include a dry chamber that the circulation chamber is disposed inside and that humidity of an internal space is controlled.

The duct block may include a discharge flow path extending straightly toward the packing block and communicating with the discharge port, and an exhaust flow path communicating with the exhaust port and bent at least once inside the duct block.

The discharge port and the exhaust port may be formed to be positioned on a central axis of an upper surface of the accommodating space.

The temperature control device may further include a packing member configured to seal a gap between the packing block and the insert in a state where the packing block is in close contact with the test tray or the insert.

According to one embodiment of the present disclosure to achieve the object, a temperature control device providing a temperature control space for a semiconductor product, includes a packing block that is in close contact with a test tray on which the insert is loaded or the insert, and has a discharge port for discharging a temperature-controlled test gas into the accommodating space and an exhaust port for exhausting the test gas from the accommodating space to an outside.

Other specific details of the present disclosure are included in the detailed description and drawings.

According to embodiments of the present disclosure, at least the following effects are achieved.

By forming the temperature control space for each semiconductor product, temperature control is possible according to the test situation of each semiconductor product.

Since the space around the semiconductor product is used as one chamber in a state where each semiconductor product is loaded into the insert, the configurations such as the existing preheating and de-heating chambers can be omitted, enabling miniaturization of the equipment.

Since the gas used for testing is circulated without being mixed with the outside air by the circulation chamber and the temperature is maintained, the time required to prepare the test environment can be minimized.

It is easy to maintain the thermal environment for the test environment by using the dry chamber with a built-in temperature control device. In addition, the dry chamber can prevent condensation from occurring during low-temperature testing.

The effects according to the present disclosure are not limited to those exemplified above, and further diverse effects are included in the present specification.

### BRIEF DESCRIPTION OF THE DRAWING

FIG. 1 is a schematic diagram of a temperature control system for providing a temperature control space for an individual semiconductor product in a test of a semiconductor product according to one embodiment of the present disclosure.

FIG. 2 is a diagram illustrating a test tray and insert according to one embodiment of the present disclosure.

FIG. 3 is a diagram conceptually illustrating a temperature control device according to one embodiment of the present disclosure.

FIG. 4 is a diagram illustrating a state in which one area temperature control unit is separated from a distribution plate according to one embodiment of the present disclosure.

FIG. 5 is a diagram when each area temperature control unit according to one embodiment of the present disclosure is viewed from above.

FIG. 6 is a view illustrating a state in which a packing block according to one embodiment of the present disclosure is coupled to a duct block.

FIG. 7 is a view illustrating a state in which the packing block according to one embodiment of the present disclosure is separated in FIG. 6.

FIG. 8 is a diagram illustrating a normal state of the packing block according to one embodiment of the present disclosure.

FIG. 9 is a diagram illustrating a state in which the packing block according to one embodiment of the present disclosure is in close contact with the test tray.

FIG. 10 is a schematic diagram illustrating a situation in which any one of the temperature control units in FIG. 5 is in close contact with the test tray.

FIG. 11 is a diagram illustrating movement of a test gas through an expansion groove according to one embodiment of the present disclosure.

FIG. 12 is a view illustrating a state in which a plurality of packing blocks are mounted on a duct block according to another embodiment of the present disclosure.

FIG. 13 is a view illustrating any one of the packing blocks in FIG. 12 separated.

FIG. 14 is a schematic cross-sectional view of a duct block and a packing block according to still another embodiment of the present disclosure.

### DETAILED DESCRIPTION

The advantages and features of the present disclosure, and the methods for achieving them, will become clear with reference to the embodiments described in detail below together with the accompanying drawings. However, the present disclosure is not limited to the embodiments disclosed below, but may be implemented in various different forms, and these embodiments are provided only to make the disclosure of the present disclosure complete and to fully inform those skilled in the art of the scope of the disclosure, and the present disclosure is defined only by the scope of the claims.

In addition, the embodiments described in this specification will be described with reference to cross-sectional views and/or schematic views, which are ideal examples of the present disclosure. Accordingly, the form of the example drawings may be modified due to manufacturing technology and/or tolerances. In addition, each component in each drawing illustrated in the present disclosure may be illustrated to some extent enlarged or reduced for convenience of explanation. The same reference numerals refer to the same components throughout the specification.

Hereinafter, the present disclosure will be described with reference to drawings for explaining a temperature control device and a temperature control system that provide a temperature control space for an individual semiconductor product in a test of a semiconductor product according to embodiments of the present disclosure.

It is obvious that the up, down, left, and right directions mentioned below may be changed during the course of implementing the disclosure, and the up, down, left, and right directions are simply used to completely disclose the present disclosure.

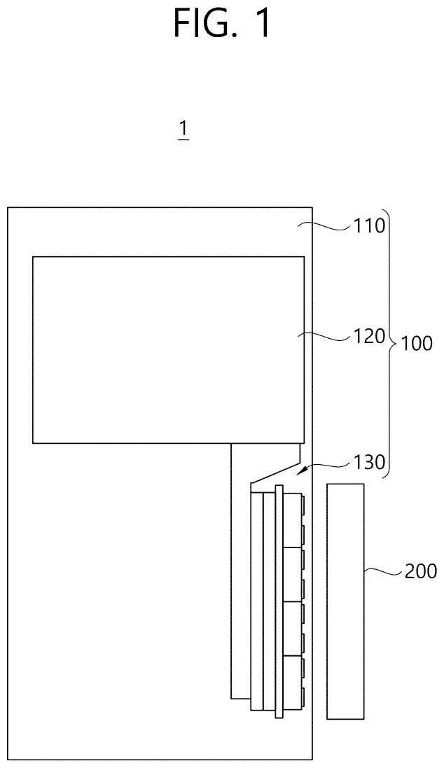

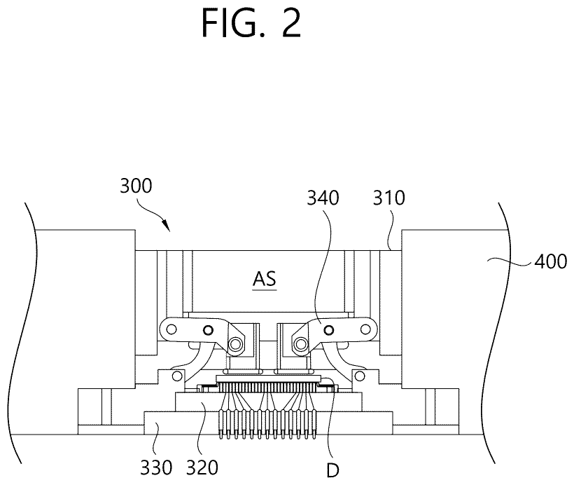

FIG. 1 is a schematic diagram of a temperature control system for providing a temperature control space for an individual semiconductor product in a test of a semiconductor product according to one embodiment of the present disclosure. In addition, FIG. 2 is a diagram illustrating a test tray and insert according to one embodiment of the present disclosure. The temperature control space mentioned below means a space in which the temperature is controlled for testing the semiconductor product, and in the present disclosure, an accommodating space AS described below may correspond to the temperature control space.

As illustrated in FIGS. 1 and 2, a temperature control system 1 according to one embodiment of the present disclosure includes a temperature control device 100, a tester 200, an insert 300, and a test tray 400.

The temperature control device 100 may create a test environment for a semiconductor product D loaded on the insert 300. For example, the semiconductor product D may exchange signals with the tester 200 under high temperature, room temperature, and/or low temperature conditions, and may be classified into good/defective/re-inspection, or the like by inspecting performance of the semiconductor product. In this case, the temperature control device 100 may control the temperature atmosphere around the semiconductor product D to create the aforementioned high temperature, room temperature, and/or low temperature conditions. For example, the high temperature may have a temperature range of 60 degrees Celsius to 200 degrees Celsius, and the low temperature may be set to a range of 0 degrees Celsius to −100 degrees Celsius. However, the temperature range may be changed in various ways in consideration of the characteristics of the semiconductor product.

This temperature control device 100 may include a dry chamber 110, a circulation chamber 120, and a duct portion 130.

The dry chamber 110 may be configured to help maintain the internal temperature of the circulation chamber 120 at a temperature suitable for the test environment and prevent condensation from forming during a low-temperature test. To this end, the internal temperature of the dry chamber 110 may be maintained within a predetermined range. Although not illustrated, a chamber temperature control unit may be installed in the dry chamber 110 to constantly control the internal temperature in order to maintain the internal temperature of the dry chamber 110 within a predetermined range. The chamber temperature control unit may be provided with various conventional heat exchange devices that form the environment inside the chamber at a constant temperature. In addition, although not illustrated, a gate may be formed in the dry chamber 110 to allow entry and exit of the duct portion 130.

More specifically, the internal temperature of the dry chamber 110 may be maintained at a temperature of approximately 60 degrees Celsius or higher. This temperature condition helps the circulation chamber 120 maintain a high temperature environment by maintaining the surroundings of the circulation chamber 120 at a higher temperature than room temperature.

In addition, the dry chamber 110 may be configured to supply dry air of a predetermined temperature with moisture removed to the inside of the dry chamber and exhaust the air inside to the outside to keep the internal space dry and ventilated. For example, the dry chamber 110 may have a fan for supplying dry air arranged on one side and a ventilation hole formed on the other side. Accordingly, the dry chamber 110 may prevent condensation from occurring by controlling the humidity and/or temperature around the duct portion 130 when the internal temperature of the circulation chamber 120 is below freezing.

The circulation chamber 120 may be disposed inside the dry chamber 110 and may provide a space in which a test gas is circulated to create a test environment around the semiconductor product D. The circulation chamber 120 may have the effect of shortening the test time by allowing the test gas to be circulated in a state of being adjusted to a temperature suitable for the test.

The duct portion 130 may be positioned adjacent to one surface of the test tray 400 loaded into the tester 200. The duct portion 130 may be configured to selectively spray the test gas circulating in the circulation chamber 120 toward the test tray 400. A detailed description thereof will be provided later.

The tester 200 may be designed to be electrically connected to the semiconductor product D loaded on the insert 300 in a state where the test tray 400 is mounted, and to exchange signals with the semiconductor product D for testing. To this end, the tester 200 may be equipped with a main board designed to exchange electrical signals for testing. A socket may be formed in the tester 200 to correspond to the arrangement of the insert 300 on the test tray 400. When the test tray 400 is mounted on the tester 200, the semiconductor product D and the test terminal of the socket may be electrically connected. The test terminal of the socket may be implemented with various known configurations, such as a pogo pin or a conductive rubber pad.

The insert 300 has a loading structure corresponding to the semiconductor product D, and a plurality of inserts can be loaded on the test tray 400. The loading structure corresponding to the semiconductor product D may mean a structure that loads the semiconductor product D according to the shape of the semiconductor product D and maintains the loaded semiconductor product D at a position corresponding to the socket of the tester 200.

The insert 300 may include an insert body 310, a contact board 320, an interface board 330, and a latch 340. The insert body 310 is formed in a structure and shape to be mounted on the test tray 400, and may be a frame that has an accommodating space AS with open one surface to load a semiconductor product D into the accommodating space AS. The contact board 320 may be in contact with a bottom surface of the semiconductor product D loaded on the insert 300. In addition, a contact terminal that is in physically and electrically contact with a terminal of the loaded semiconductor product D may be formed on the contact board 320. The interface board 330 is disposed on the rear surface of the contact board 320, and may have a wiring pattern that is electrically connected to the contact terminal and an external terminal that is exposed to the outside to be electrically connected to a socket. The external terminal may have an extended pitch compared to the contact terminal so as to facilitate alignment with the socket. The wiring pattern may be formed to electrically connect the external terminal and the contact terminal. The latch 340 is a device for maintaining the position of the semiconductor product D loaded on the insert body 310, and may be implemented in various configurations known in the art. For example, the latch 340 may be a clamper-type member capable of holding the semiconductor product D with elastic force.

With this configuration, in one embodiment of the present disclosure, the semiconductor product D may be tested by being electrically connected to the socket through the insert 300 in a state where the test tray 400 is mounted and/or in close contact with the tester 200.

The test tray 400 may have a groove formed to accommodate an individual insert body 310 at positions corresponding to the socket. Since the general configuration of the test tray 400 is known in the past, a detailed description is omitted.

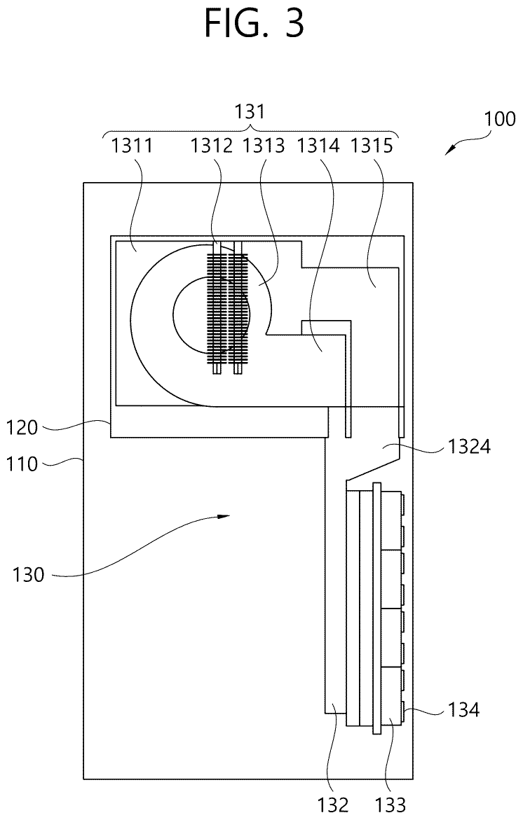

Hereinafter, with reference to FIG. 3, the duct portion 130 according to one embodiment of the present disclosure will be described. FIG. 3 is a drawing conceptually illustrating a temperature control device according to one embodiment of the present disclosure.

As illustrated in FIG. 3, a duct portion 130 according to one embodiment of the present disclosure may include a gas circulator 131, a distribution plate 132, a duct block 133, and a packing block 134.

The gas circulator 131 may be configured to circulate a test gas and control temperature of the test gas. For example, the test gas may be temperature-controlled air or gas. The gas circulator 131 may include a circulation housing 1311, a gas temperature controller 1312, a fan 1313, a supply pipe 1314, and a collection pipe 1315.

The circulation housing 1311 may be a housing positioned inside the circulation chamber 120 and having a fan 1313 built in the circulating housing. The gas temperature controller 1312 may be built into or adjacent to the circulation housing 1311 and may be formed to control the temperature atmosphere inside the circulation chamber 120. For example, the gas temperature controller 1312 may be provided with various heat exchange devices known in the art. The fan 1313 may be a blower that circulates the test gas inside the circulation chamber 120. The supply pipe 1314 may be formed to deliver the test gas supplied from the fan 1313 to the distribution plate 132, and the collection pipe 1315 may be formed to move the test gas exhausted from the distribution plate 132 back into the circulation chamber 120.

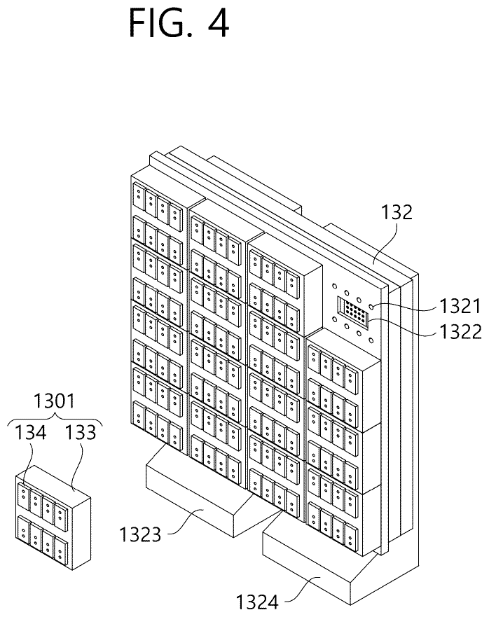

The distribution plate 132 may form a circulation path of the test gas between a plurality of duct blocks 133 and the gas circulator 131. A description thereof will be given later with reference to FIG. 4.

The plurality of duct blocks 133 are connected to one surface of the distribution plate 132, and may distribute and deliver the test gas delivered from the gas circulator 131 to the plurality of packing blocks 134. In addition, the duct block 133 may be connected to the distribution plate 132 so as to deliver the test gas exhausted through the connected packing block 134 back to the distribution plate 132.

The packing block 134 may be in close contact with one surface of the test tray 400 (refer to FIG. 2) or the insert 300 (refer to FIG. 2) in a state where the test tray 400 (refer to FIG. 2) is mounted on the tester 200 (refer to FIG. 1) to separate the accommodating space AS (refer to FIG. 2) and the external space. In addition, the packing block 134 may deliver the test gas supplied from the duct block 133 into the accommodating space AS, thereby controlling the internal temperature of the accommodating space AS.

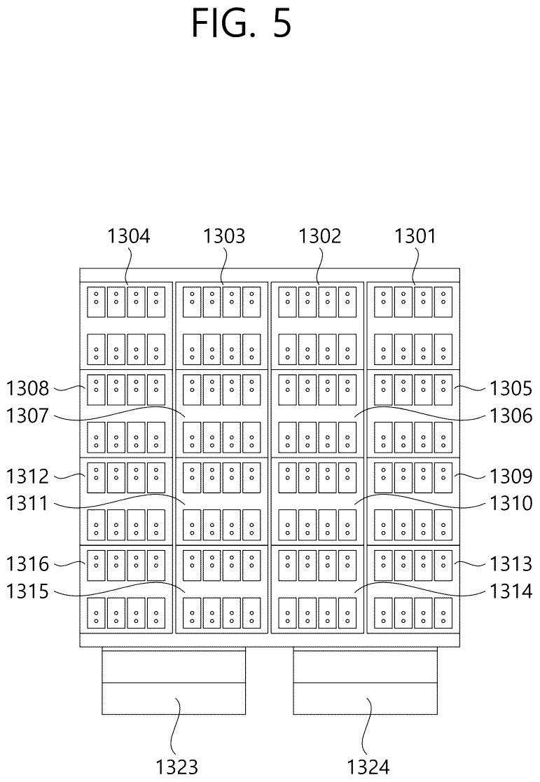

Hereinafter, with reference to FIGS. 4 and 5, the gas distribution structure of the distribution plate 132 and the area in charge of each duct block 133 will be described. For convenience of explanation, in the following, when one duct block 133 and the packing block 134 mounted on the one duct block 133 are referred to at once, they are referred to as area temperature control units 1301, 1302, 1303, 1304, 1305, 1306, 1307, 1308, 1309, 1310, 1311, 1312, 1313, 1314, 1315, and 1316 (hereinafter, referred to as 1301 to 1316).

FIG. 4 is a diagram illustrating a state in which one area temperature control unit is separated from a distribution plate according to one embodiment of the present disclosure. In relation to this, FIG. 5 is a diagram when each area temperature control unit according to one embodiment of the present disclosure is viewed from above.

As illustrated in FIGS. 4 and 5, the plurality of area temperature control units 1301 to 1316 may be mounted on one surface of the distribution plate 132. In this case, the distribution plate 132 may be formed to have an area corresponding to the test tray 400 (refer to FIG. 2), and each of the area temperature control units 1301 to 1316 may be responsible for temperature control for one area on the test tray 400. Accordingly, the packing block 134 of any one of the area temperature control units 1301 to 1316 may be responsible for the insert 300 (refer to FIG. 2) adjacent to each other in the test tray 400. This may be in consideration of the fact that the thermal environments of the inserts 300 adjacent to each other are similar while a test is being performed in the tester 200 (refer to FIG. 1). To this end, each of the area temperature control units 1301 to 1316 may be equipped with a heat exchange unit so that the temperature can be controlled independently from other area temperature control units 1301 to 1316. A description of the heat exchange unit will be provided later.

On one surface of the distribution plate 132, an individual supply flow path 1321 and a collection/recovery flow path 1322 for fluid communication with each of the area temperature control units 1301 to 1316 may be formed. A circulation path of the test gas between the duct block 133 and the gas circulator 131 (refer to FIG. 1) may be formed by the individual supply flow path 1321 and the collection/recovery flow path 1322.

The individual supply flow path 1321 may form a gas transport path perpendicular to the packing block 134 so that the temperature-controlled test gas can be supplied to the accommodating space AS while minimizing heat loss. To this end, the individual supply flow path 1321 may penetrate one by one corresponding to the discharge port so as to have the same central axis as the discharge port of each packing block 134.

The collection/recovery flow path 1322 can form a gas transfer path that collects the test gases recovered from each packing block 134 and then recovers the test gases to the gas circulator 131. Since the test gases recovered to the gas circulator 131 are collected and recovered by the collection/recovery flow path 1322, the transfer path of the test gases moving from the packing block 134 to the gas circulator 131 is bent at least once.

Specifically, the plurality of individual supply flow paths 1321 connected to any one of the area temperature control units 1301 to 1316 may be positioned one by one along an edge of an imaginary square on one surface of the distribution plate 132. That is, when the central axes of the plurality of individual supply flow paths 1321 are connected, a square is drawn on one surface of the distribution plate 132. In this regard, the collection/recovery flow path 1322 connected to any one of the area temperature control units 1301 to 1316 may be positioned at the center of the square formed by the individual supply flow paths 1321.

In the examples of FIGS. 4 and 5, 16 area temperature control units 1301 to 1316 are arranged in 4 rows and 4 columns, and eight packing blocks 134 are mounted on any one of the area temperature control units 1301 to 1316. In this case, eight individual supply flow paths 1321 and one collection/recovery flow path 1322 are formed in the distribution plate 132 at the position corresponding to each of the area temperature control units 1301 to 1316, so that a total of 128 individual supply flow paths 1321 and 16 collection/recovery flow paths 1322 may exist.

However, the distribution plate 132 and/or the area temperature control unit 1301 to 1316 according to the present disclosure are not limited to this number and/or arrangement, and the above-described number and/or arrangement may be variously changed depending on the situation of the test tray 400, the insert 300, and/or the semiconductor product D.

A plurality of connecting ducts 1323 and 1324 connected to the supply pipe 1314 (refer to FIG. 3) and/or the collection pipe 1315 (refer to FIG. 3) may be formed at an end of the distribution plate 132 adjacent to the circulation chamber 120.

For example, the plurality of connecting ducts 1323 and 1324 may be configured such that any one of the ducts connects the individual supply flow paths 1321 of the distribution plate 132 and the supply pipe 1314 and the other connects the collection/recovery flow paths 1322 and the collection pipe 1315.

As another example, the connecting ducts 1323 and 1324 may connect the individual supply flow paths 1321 of adjacent area temperature control units 1301 to 1316 and the supply pipe 1314 for responsible of supplying and recovering of the adjacent area temperature control units 1301 to 1316, and may connect the collection/recovery flow paths 1322 of adjacent area temperature control units 1301 to 1316 and the collection pipe 1315. For example, in the examples of FIGS. 4 and 5, the left connecting duct 1323 may establish the gas circulation paths of the eight left area temperature control units 1303, 1304, 1307, 1308, 1311, 1312, 1315 and 1316, and the right connecting duct 1324 may establish the gas circulation paths of the eight right area temperature control units 1301, 1302, 1305, 1306, 1309, 1310, 1313 and 1314.

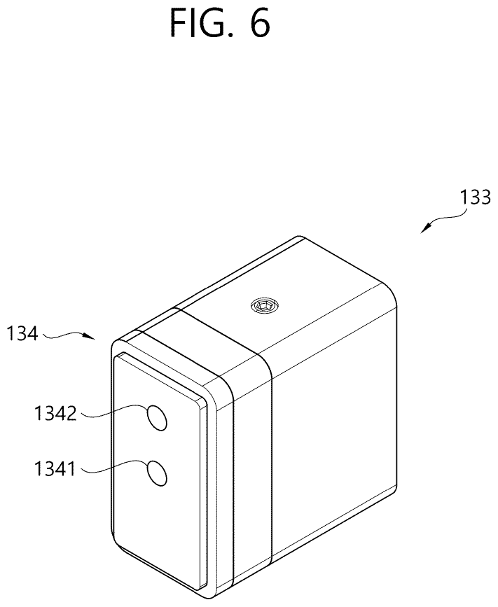

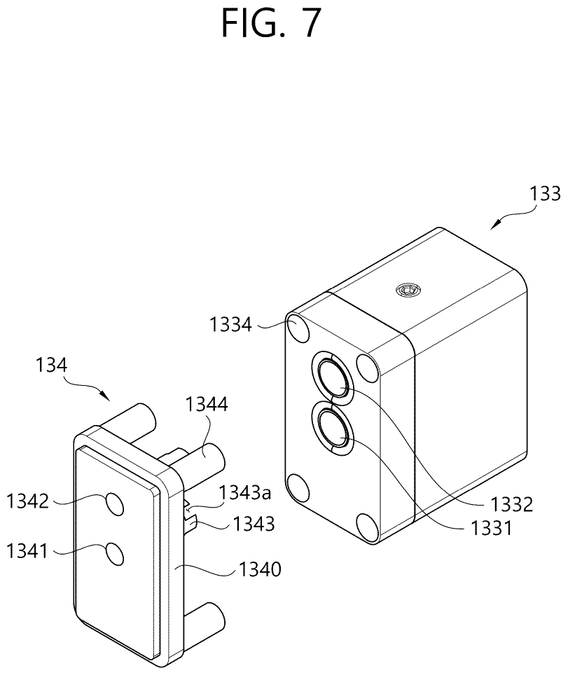

Hereinafter, with reference to FIGS. 6 and 7, the packing block 134 and the duct block 133 according to an embodiment of the present disclosure will be additionally described. In order to simply illustrate the coupling structure of the two components, only a portion of the duct block 133 that is coupled to any one of the packing blocks 134 is illustrated separately in FIGS. 6 and 7. First, FIG. 6 is a view for explaining a state in which the packing block according to an embodiment of the present disclosure is coupled to the duct block. In this regard, FIG. 7 is a view illustrating a state in which the packing block according to an embodiment of the present disclosure is separated in FIG. 6.

Referring to FIGS. 6 and 7, the packing block 134 may be retractably coupled to one surface of the duct block 133. To this end, the packing block 134 may include a push end 1343 and a guide end 1344 protruding in a rear surface direction of the packing plate 1340, and the duct block 133 may have through holes that accommodate the push end 1343 and the guide end 1344, respectively.

The packing plate 1340 may be a plate-shaped member that is in close contact with the test tray 400 (refer to FIG. 2) and separates the accommodating space AS (refer to FIG. 2) and the external space. The packing plate 1340 may have a stepped shape with an edge portion thereof recessed in the rear surface direction. In this case, the recessed portion may push the test tray 400 during the test process, and the protruding portion in the center may serve as the ceiling of the accommodating space AS.

A discharge port 1341 and an exhaust port 1342 may be formed in the packing plate 1340. The discharge port 1341 may be connected to a discharge flow path 1331 described later, and discharge the test gas into the accommodating space AS. The exhaust port 1342 may be connected to an exhaust flow path 1332 described later, and exhaust the test gas discharged from the accommodating space AS to the outside. A partial section of each of the discharge port 1341 and the exhaust port 1342 may be formed in the packing plate 1340, and other sections may be formed in the push end 1343. For example, the discharge port 1341 and the exhaust port 1342 may be formed to penetrate approximately vertically from one surface of the packing plate 1340 to an end of the push end 1343.

The packing plate 1340 is formed in an approximately rectangular shape, and the discharge port 1341 and the exhaust port 1342 may be aligned on a central axis passing through a center of a short side of the packing plate 1340. Accordingly, when the packing plate 1340 is in close contact with the test tray 400, the discharge port 1341 and the exhaust port 1342 may be positioned on the central axis of the upper surface of the accommodating space AS. Meanwhile, the discharge port 1341 may be positioned at the center on one surface of the packing plate 1340, and the exhaust port 1342 may be positioned eccentrically to one side of the packing plate 1340.

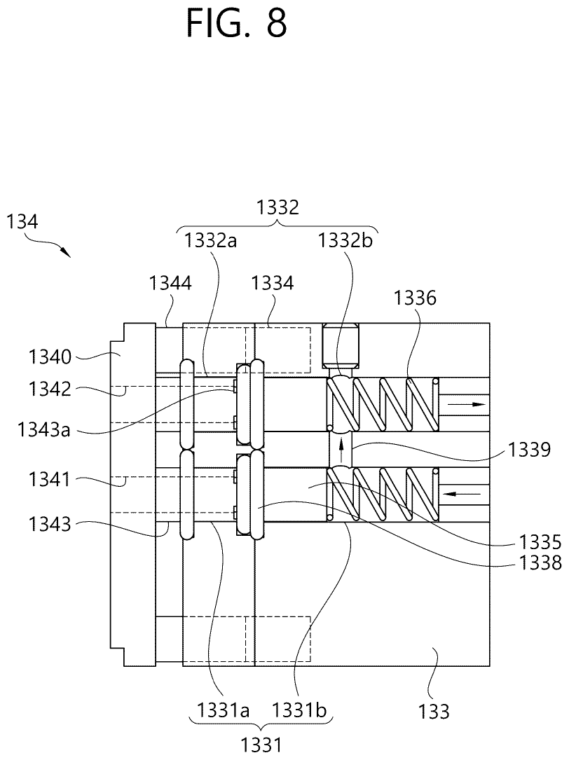

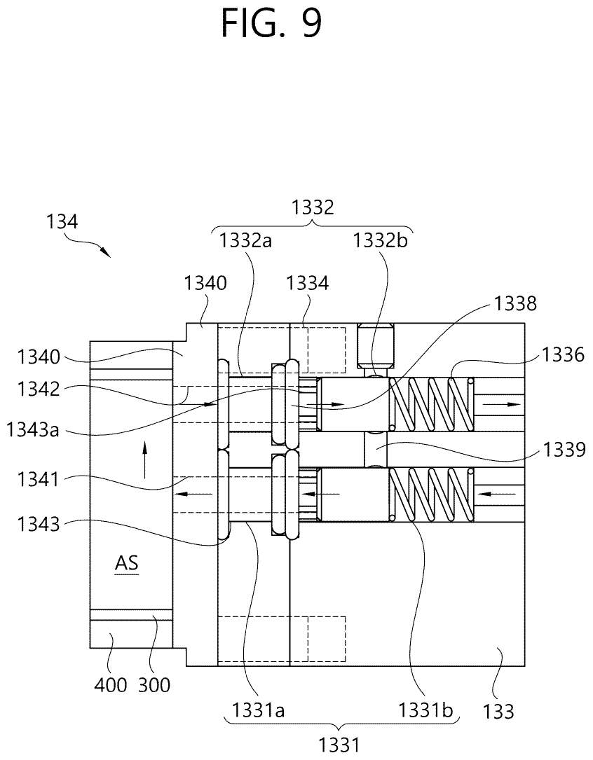

The push end 1343 may be a cylindrical member having a through hole extending from the rear surface of the packing plate 1340 toward the duct block 133. In this case, the through hole penetrating one end and the other end of the push end 1343 may be the discharge port 1341 or the exhaust port 1342. The discharge port 1341 and the exhaust port 1342 may be formed by penetrating along the central axis of the push end 1343. The circulation path of the test gas changes according to the advancement and retreat of the push end 1343, and this will be described later with reference to FIGS. 8 and 9. Among the two push ends 1343, the push end 1343 forming the discharge port 1341 may be located at the center of the rear surface of the packing plate 1340, and the push end 1343 forming the exhaust port 1342 may be eccentric to one side on the rear surface of the packing plate 1340.

The guide ends 1344 may be axial members extending from each of the four corners located on the rear surface of the packing plate 1340 toward the duct block 133. The plurality of guide ends 1344 may extend along the advancing and retreating direction of the packing block 134 to guide the advancing and retreating movement of the packing block 134. In this case, it is sufficient if the guide ends 1344 are formed to extend along the advancing and retreating direction to guide the movement direction, and the arrangement and number of the guide ends 1344 may be changed according to an embodiment.

A plurality of push ends 1343 may be accommodated in the discharge flow path 1331 and the exhaust flow path 1332 among the through holes formed in the duct block 133, respectively. The push end 1343 located at the rear of the discharge port 1341 may be inserted into the discharge flow path 1331, and the push end 1343 located at the rear of the exhaust port 1342 may be inserted into the exhaust flow path 1332. In this case, the discharge flow path 1331 is fluidically connected to the aforementioned individual supply flow path 1321 (refer to FIG. 4) so as to deliver the test gas to the discharge port 1341. Meanwhile, the exhaust flow path 1332 is fluidically connected to the aforementioned collection/recovery flow path 1322 so as to deliver the test gas to the collection/recovery flow path 1322.

A guide hole 1334 may be formed through a position corresponding to each guide end 1344 in the duct block 133. The depth of the guide hole 1334 may be similar to or slightly longer than the protruding length of the guide end 1344. In addition, the guide hole 1334 may accommodate the guide end 1344 with a slight clearance. The guide end 1344 may advance and retreat along the inner wall of the guide hole 1334 and guide the movement direction of the packing block 134.

Hereinafter, with reference to FIGS. 8 and 9, a change in the gas circulation path according to the position of the packing block 134 according to one embodiment of the present disclosure will be described. FIG. 8 is a diagram illustrating a normal state of the packing block according to one embodiment of the present disclosure. In relation to this, FIG. 9 is a diagram illustrating a state in which a packing block according to one embodiment of the present disclosure is in close contact with the test tray.

As illustrated in FIGS. 8 and 9, the push end 1343 according to one embodiment of the present disclosure may have a gas communication groove 1343a formed at the free end. Accordingly, the discharge port 1341 and the exhaust port 1342 communicate with the gas communication groove 1343a at the distal end, and are capable of fluid communication with the outside through the gas communication groove 1343a. The gas communication groove 1343a may be a groove formed by being recessed in the rear surface direction of the packing plate 1340 at the free end of the push end 1343. More specifically, a plurality of gas communication grooves 1343a may be formed at equal intervals along the outer circumference of the push end 1343. For example, the gas communication groove 1343a may be a substantially rectangular groove that penetrates. However, the shape of the gas communication groove 1343a is exemplary, and the gas communication groove 1343a may be provided as a groove of various shapes penetrating the distal end of the push end 1343.

Meanwhile, the discharge flow path 1331 may be divided into a first discharge flow path 1331a and a second discharge flow path 1331b. The first discharge flow path 1331a may accommodate a push end 1343 and have one end facing the rear surface of the packing plate 1340 and the other end extending toward the rear surface of the duct block 133. The second discharge flow path 1331b may have one end connected to the other end of the first discharge flow path 1331a, and the other end fluidically communicating with the individual supply flow path 1321 (refer to FIG. 4). In this case, the second discharge flow path 1331b may be formed to have a slightly larger inner diameter than the first discharge flow path 1331a and the same central axis.

In addition, the front end of the second discharge flow path 1331b may be provided to have a width capable of accommodating a push body 1335, and the rear end thereof may be provided to have a width smaller than the push body 1335. A stepped shape of the second discharge flow path 1331b may be a shape to prevent the push body 1335 from being separated from the front end of the second discharge flow path 1331b. The front end of the second discharge flow path 1331b may accommodate the push body 1335 and an elastic member 1336 that supports the push body 1335. In this case, the elastic member 1336 may be supported by the inner wall of the stepped shape formed due to the difference in inner diameter between the front end and the rear end of the second discharge flow path 1331b.

Similarly, the exhaust flow path 1332 may be divided into a first exhaust flow path 1332a and a second exhaust flow path 1332b. The first exhaust flow path 1332a may accommodate the push end 1343, and have one end facing the rear surface of the packing plate 1340 and the other end extending toward the rear surface of the duct block 133. The second exhaust flow path 1332b may have one end connected to the other end of the first exhaust flow path 1332a and the other end fluidically communicating with the collection/recovery flow path 1322 (refer to FIG. 4). In this case, the second exhaust flow path 1332b may be formed to have a slightly larger inner diameter than the first exhaust flow path 1332a and have the same central axis.

In addition, the front end of the second exhaust flow path 1332b may be provided to have a width capable of accommodating the push body 1335, and the rear end thereof may be provided to have a width smaller than the push body 1335. The stepped shape of the second exhaust flow path 1332b may be a shape to prevent the push body 1335 from being separated from the front end of the second exhaust flow path 1332b. The front end of the second exhaust flow path 1332b may accommodate the push body 1335 and an elastic member 1336 that supports the push body 1335. In this case, the elastic member 1336 may be supported by the inner wall of the stepped shape formed due to the difference in inner diameter between the front end and the rear end of the second exhaust flow path 1332b.

Meanwhile, the first discharge flow path 1331a and the first exhaust flow path 1332a may be formed with the same or similar specifications. Similarly, the second discharge flow path 1331b and the second exhaust flow path 1332b may be formed with the same or similar specifications. The push body 1335 may be disposed inside the second discharge flow path 1331b and the second exhaust flow path 1332b. The push body 1335 may be provided so that the diameter of the bottom surface is larger than the inner diameters of the first discharge flow path 1331a and the first exhaust flow path 1332a, but corresponding to or slightly smaller than the inner diameters of the front ends of the second discharge flow path 1331b and the second exhaust flow path 1332b.

The elastic member 1336 may be formed to elastically support the push body 1335 in the direction of the packing plate 1340. For example, the elastic member 1336 may have one end connected to the push body 1335 and the other end connected to the inner wall of the duct block 133 forming the second discharge flow path 1331b or the second exhaust flow path 1332b. For example, the elastic member 1336 may utilize a stepped structure caused by a width difference between the front end and the rear end of the second discharge flow path 1331b (or the second exhaust flow path) so that the other end may be supported by the inner wall of the duct block 133.

Due to the elastic support of the elastic member 1336, the push body 1335 may be in close contact with one end of the second discharge flow path 1331b or the second exhaust flow path 1332b in the absence of an external force. In this case, since the diameter of the bottom surface of the push body 1335 is larger than the inner diameters of the first discharge flow path 1331a and the first exhaust flow path 1332a, the push body 1335 can no longer advance toward the first discharge flow path 1331a and the first exhaust flow path 1332a. Therefore, due to the push body 1335, in the absence of external force, fluid communication between the first discharge flow path 1331a and the second discharge flow path 1331b and fluid communication between the first exhaust flow path 1332a and the second exhaust flow path 1332b can be prevented.

In the above-described example, the push body 1335 is opened and closed by elastic force without external manipulation, but the present disclosure is not limited thereto. For example, according to an embodiment, an advancement/retreat shaft (not illustrated) that supports the push body 1335 to be positioned on the central axis of the second discharge flow path 1331b or the second exhaust flow path 1332b and advances/retracts according to external manipulation may be connected to the rear end of the push body 1335.

A packing ring 1338 may be disposed near the boundary of one end of the second discharge flow path 1331b so as to block a small gap between the push body 1335 and the first discharge flow path 1331a in a state where the push body 1335 is in close contact with the front end of the second discharge flow path 1331b. For example, the packing ring 1338 may be provided as an elastic ring-shaped member. As an example, the packing ring 1338 may be an O-ring. In this case, the inner diameter of the packing ring 1338 may be provided to be slightly larger than the diameter of the push end 1343. As in the case of the discharge flow path 1331, the packing ring 1338 may also be disposed between the first exhaust flow path 1332a and the second exhaust flow path 1332b.

A circulation induction flow path 1339 connecting the second discharge flow path 1331b and the second exhaust flow path 1332b may be further formed in the duct block 1333. The circulation induction flow path 1339 may be formed at a location where both ends are not covered by the push body 1335 in the maximum forward state.

The packing block 134 may be formed to move together with the push body 1335. In this case, the push end 1343 may be formed to have a diameter corresponding to the first discharge flow path 1331a or the first exhaust flow path 1332a. Accordingly, the push end 1343 may enter the second discharge flow path 1331b or the second exhaust flow path 1332b along the push body 1335 while passing through the packing ring 1338 when the push body 1335 moves backward. To this end, the push end 1343 and the push body 1335 may be aligned to have the same central axis.

In order for the packing block 134 to move together with the push body 1335, a restoring force providing member (not illustrated) that elastically supports the guide end 1344 in a direction that pulls the guide end 1344 into the guide hole may be disposed inside the guide hole 1334. In this case, the restoring force providing member may be provided with a restoring force that is weaker than that of the elastic member 1336. This is to prevent the push end 1343 from pushing the push body 1335 and entering the second discharge flow path 1331b or the second exhaust flow path 1332b in a state where there is no external force. For example, the elastic member 1336 may be provided as a helical spring, and the restoring force providing member may be provided as a helical spring that is disposed to surround the guide end 1344.

As another example, the push body 1335 and the push end 1343 may be connected to each other as one body so that the packing block 134 moves together with the push body 1335.

Based on the description above, the circulation path of the test gas in the absence of external force is described with reference to FIG. 8.

As illustrated in FIG. 8, when there is no external force, the packing plate 1340 may maintain a state of protruding forward due to the elastic force of the elastic member 1336. In this case, although not illustrated, in order to prevent the packing block 134 from being separated from the duct block 133 due to the elastic force of the elastic member 1336, a stopper that limits the forward distance of the guide end 1344 may be formed inside the guide hole 1334.

In this state, the test gas moving along the second discharge flow path 1331b is blocked by the push body 1335 and the packing ring 1338 and cannot flow in the direction of the first discharge flow path 1331a. Therefore, in the state of FIG. 8, the test gas may pass through the second discharge flow path 1331b and enter the second exhaust flow path 1332b through the circulation induction flow path 1339 as indicated by the arrow in FIG. 8 and be recovered by the gas circulator 131 (refer to FIG. 3).

The state of FIG. 8 is a standby state in which no test is performed on a semiconductor product, and the test gas inside the gas circulator 131 may be preheated to a temperature suitable for the test and then circulated and put on standby. Accordingly, according to one embodiment of the present disclosure, the test gas may be prepared in advance at a suitable temperature before the test is performed, thereby shortening the time required for the test.

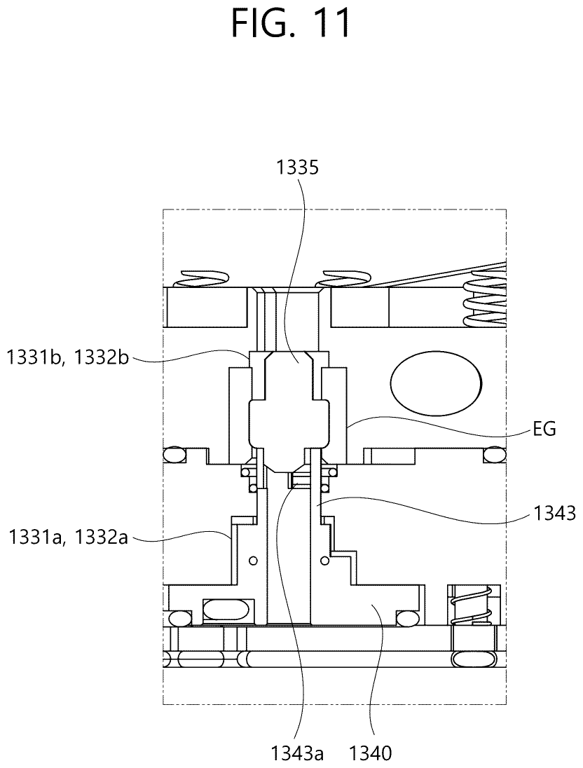

Meanwhile, when the test is in progress, the test tray 400 may be in close contact with the packing block 134 as illustrated in FIG. 9 by an external operating device. As a result, the packing block 134 may overcome the elastic force of the elastic member 1336 and be inserted into the inside of the duct block 133. As a result, the plurality of push ends 1343 may enter the second discharge flow path 1331b and the second exhaust flow path 1332b, respectively. Accordingly, the rear end of each push end 1343 may be positioned inside the second discharge flow path 1331b or the second exhaust flow path 1332b, so that the gas communication groove 1343a can communicate with the fluid inside the second discharge flow path 1331b or the second exhaust flow path 1332b. In this case, an expansion groove EG (refer to FIG. 11) may be formed inside the second discharge flow path 1331b or the second exhaust flow path 1332b to facilitate the introduction of gas into the gas communication groove 1343a. This will be described later with reference to FIG. 11.

The test gas flowing between the push body 1335 and the inner wall of the duct block 133 forming the second discharge flow path 1331b may proceed along the existing flow direction as indicated by the arrow in FIG. 9, enter the discharge port 1431 through the gas communication groove 1343a, and finally be discharged into the accommodating space AS. Similarly, the test gas passing through the inside of the accommodating space AS may pass through the gas communication groove 1343a through the exhaust port 1342 located above the insert 300, and then pass through the second exhaust flow path 1332b to be recovered into the gas circulator 131.

Meanwhile, since the push body 1335 also moves backwards as much as the push end 1343 moves, the push body 1335 may be positioned on both sides of the circulation induction flow path 1339. As a result, the flow of the test gas through the circulation induction flow path 1339 is prevented, so that the test gas can be circulated along a path roughly like the arrow in FIG. 9.

Therefore, according to the present disclosure, there is an advantage in that the circulation path of gas can be changed simply by bringing the insert 300 or test tray 400 into close contact with the outside.

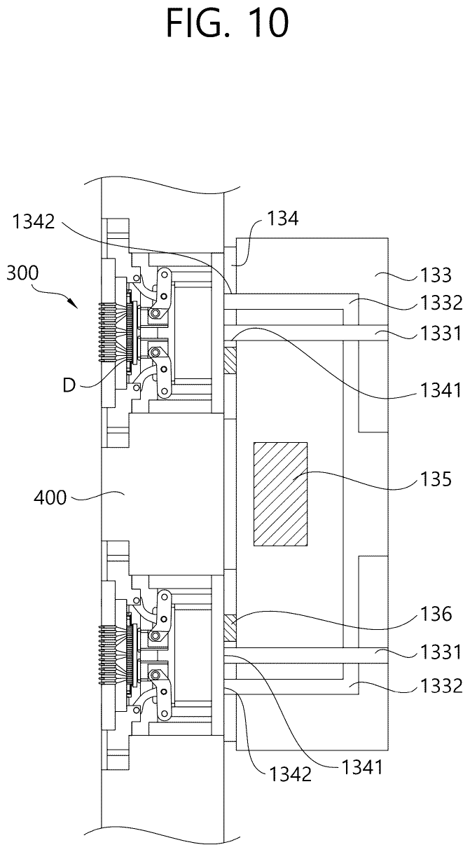

Hereinafter, with reference to FIG. 10, a temperature control function for each region according to one embodiment of the present disclosure will be described. FIG. 10 is a schematic diagram illustrating a situation in which any one of the temperature control units in FIG. 5 is in close contact with the test tray.

As illustrated in FIG. 10, each of the area temperature control units 1301 to 1316 (refer to FIG. 5) may include a heat exchange unit 135 that is disposed lengthwise between a plurality of packing blocks 134. The heat exchange unit 135 may be disposed in a duct block 133 and configured to control the temperature of the test gas distributed to the plurality of packing blocks 134. For example, the heat exchange unit 135 may be extended lengthwise in a space between rows of packing blocks 134 arranged in a plurality of rows. As an example, the heat exchange unit 135 may be provided as a conventionally known temperature control unit, such as a heater or a thermoelectric element.

The discharge flow path 1331 and discharge port 1341 for each packing block 134 are disposed close to the heat exchange unit 135, and the exhaust flow path 1332 and exhaust port 1342 may be arranged relatively far from the heat exchange unit 135. This may be to allow the heat of the heat exchange unit 135 to be quickly delivered to the discharge flow path 1331.

Since the discharge flow path 1331 extends in a straight line toward the packing block 134 and is connected to the discharge port 1341, the test gas can quickly pass through the interior of the duct block 133. Therefore, in order to increase the heat exchange efficiency for the test gas, the heat exchange unit 135 and each discharge flow path 135 need to be disposed adjacent to each other.

Meanwhile, the exhaust flow path 1332 may be bent at least once inside the duct block 133 so that the second exhaust flow path 1332b (refer to FIGS. 8 to 9) may be connected to the collection/recovery flow path 1322 (refer to FIG. 4). This bent path of the exhaust flow path 1332 may increase the energy efficiency for preserving the temperature of the duct block 133 by increasing the time for the exhausted test gas to pass through the inside of the duct block 133 after the heat exchange. That is, the increase in the residence time of the test gas passing through the inside of the duct block 133 may have the effect of preventing the temperature of the duct block 133 from dropping to a predetermined temperature or less by inducing sufficient heat exchange between the duct block 133 and the test gas.

Each packing block 134 may have a temperature measurement sensor 136 built into the packing block. For example, the temperature measurement sensor 136 may be disposed in an area adjacent to the discharge port 1341 in the packing block 134. This may be done by placing the temperature measurement sensor 136 in an area adjacent to the discharge port 1341 located immediately above the semiconductor product D in the packing block 134 in order to detect the temperature of the area adjacent to the semiconductor product D. The temperature measurement sensor 136 may be provided with various sensors known in the art. For example, the temperature measurement sensor 136 may be an RTD sensor that uses a change in resistance value depending on temperature.

In the above-described example, the temperature measurement sensor 136 is built in the packing block 134, but the present disclosure is not limited to such an example. For example, the temperature measurement sensor 136 may be installed in an area adjacent to the packing block 134 in the duct block 133.

Meanwhile, the heat exchange unit 135 and temperature measurement sensor 136 built into the duct block 133 can have the following effects.

During the test process, the inserts 300 located in the center inside the test tray 400 are surrounded by inserts 300 undergoing testing, and thus may be more likely to heat up than the inserts 300 located on the periphery. That is, during the test process, the temperature environment of each area of the test tray 400 may be different from each other.

In this case, in the case of the present disclosure, by arranging the heat exchange unit 135 in the duct block 133 that is in close contact with the inserts 300 positioned adjacent to each other, the temperature difference between areas can be minimized. In addition, the temperature measurement sensor 136 provides the actual temperature measurement value at a location adjacent to each semiconductor product D, thereby allowing the user to recognize the current test situation and grasp the temperature status of each insert 300.

Hereinafter, the expansion groove EG according to one embodiment of the present disclosure will be described with reference to FIG. 11. FIG. 11 is a diagram illustrating movement of the test gas through the expansion groove according to one embodiment of the present disclosure.

As illustrated in FIG. 11, at an end of the second discharge flow path 1331b and/or the second exhaust flow path 1332b, at least one expansion groove EG formed in a direction that expands the inner diameter of the second discharge flow path 1331b and/or the second exhaust flow path 1332b may be formed along the edge of the second discharge flow path 1331b and/or the second exhaust flow path 1332b. The expansion groove EG may be formed to have a predetermined gap from the push body 1335 regardless of the state of the push body 1335.

Due to this, the expansion groove EG may surround the space where the gas communication groove 1343a is located, in a state where the push end 1343 has entered as far as possible into the interior of the second discharge flow path 1331b and/or the second exhaust flow path 1332b, as illustrated in FIG. 11. Accordingly, in a state where the push body 1335 is pushed by the push end 1343 and is accommodated as far as possible into the interior of the second discharge flow path 1331b and/or the second exhaust flow path 1332b, as illustrated in FIG. 11, the movement of gas between the second discharge flow path 1331b and/or the second exhaust flow path 1332b and the gas communication groove 1343a may proceed smoothly through the expansion groove EG. Therefore, the expansion groove EG has the effect of securing an appropriate flow rate of test gas moving through the gas communication groove 1343a.

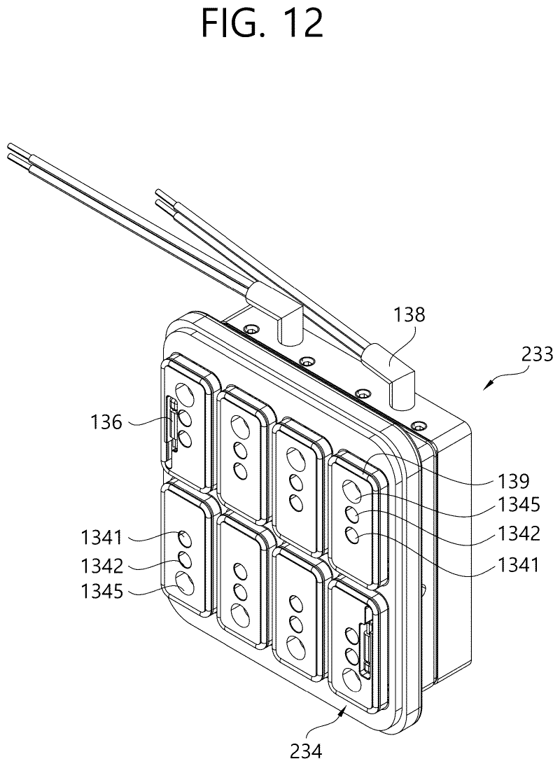

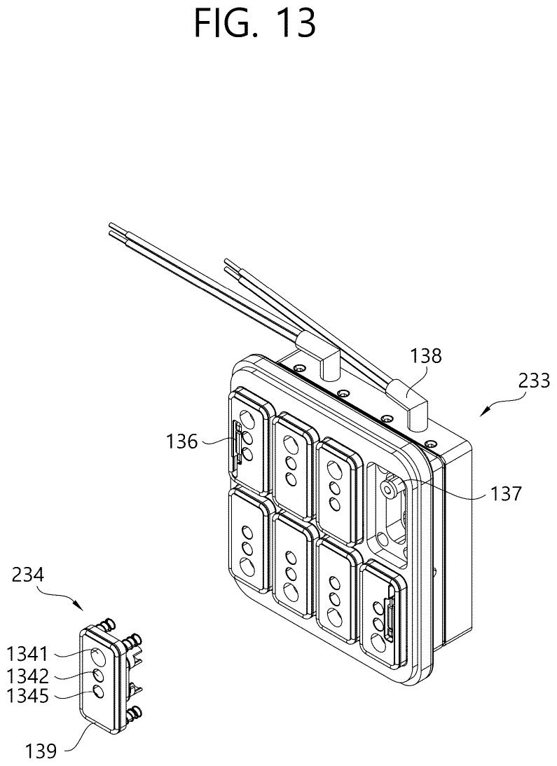

Hereinafter, a duct block and a packing block according to another embodiment of the present disclosure will be described with reference to FIGS. 12 and 13. For convenience of explanation, parts similar to the above-described embodiment are given the same reference numerals, and descriptions of common parts are omitted. FIG. 12 is a view illustrating a state in which a plurality of packing blocks are mounted on the duct block according to another embodiment of the present disclosure. In this regard, FIG. 13 is a view illustrating any one of the packing blocks in FIG. 12 separated.

As illustrated in FIGS. 12 and 13, a packing block 234 according to another embodiment of the present disclosure may further have an auxiliary fluid exhaust port 1345 formed in addition to a discharge port 1341 and an exhaust port 1342 on one surface. In addition, a duct block 233 according to another embodiment may further include an auxiliary fluid discharge pipe 137 disposed to penetrate the auxiliary fluid exhaust port 1345. The auxiliary fluid discharge pipe 137 may discharge an auxiliary fluid into the accommodating space in order to control the temperature of each semiconductor product D. Here, the auxiliary fluid may be a fluid having a different temperature from the test gas. For example, the auxiliary fluid may be liquid nitrogen (LN2). In order to supply the auxiliary fluid to the auxiliary fluid discharge pipe 137, an auxiliary fluid supply pipe 138 may be additionally connected to the duct block 233.

In addition, the packing block 234 according to another embodiment may further include a packing member 139 arranged along the edge. The packing member 139 may secure a sealing force for the accommodating space by sealing the gap between the packing block 234 and the insert in a state where the packing block 234 is in close contact with the test tray or the insert. For example, the packing member 139 may be formed of sealing silicone, rubber, or the like having a roughly rectangular shape.

According to another embodiment of the present disclosure, the following effects may be additionally achieved. As described above, each insert may have a slightly different thermal environment depending on the position of the insert within the test tray. Since the temperature control device according to another embodiment of the present disclosure further includes the auxiliary fluid discharge pipe 137, the temperature of each insert may be controlled differently, thereby ensuring improved temperature uniformity for all inserts on the test tray.

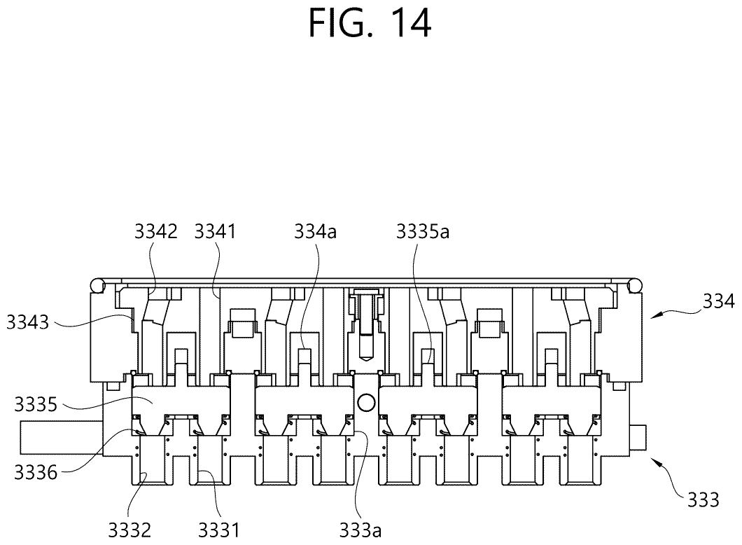

Hereinafter, with reference to FIG. 14, the structures of a duct block and a packing block according to still another embodiment of the present disclosure will be described. FIG. 14 is a schematic cross-sectional view of the duct block and the packing block according to still another embodiment of the present disclosure. Hereinafter, the direction will be described assuming that a duct block 333 is located below a packing block 334. In order to avoid redundant description, the same or similar parts as those of the above-described embodiments will be omitted, and the differences will be described intensively.

As illustrated in FIG. 14, according to still another embodiment of the present disclosure, the packing block 334 may be formed to correspond to a plurality of inserts 300 (refer to FIG. 2). A pair of discharge ports 3341 and a pair of exhaust ports 3342 may be formed in the packing block 334 to correspond to each insert 300. In this case, although FIG. 14 illustrates that the discharge port 3341 is positioned to the right of the exhaust port 3342, the opposite may also be possible. Meanwhile, similar to the above-described embodiment, the discharge port 3341 and the exhaust port 3342 may extend along the central axis of a push end 3343 protruding in one direction from the packing block 334.

A key feature of the temperature control device according to the embodiment illustrated in FIG. 14 is that the circulation path of the test gas can be controlled by a single push body 3335. More specifically, according to the present embodiment, the push body 3335 may be placed in a push body receiving groove 333a formed by being recessed in the upper surface of the duct block 333. The push body receiving groove 333a may be connected to a discharge flow path 3331 and an exhaust flow path 3332 through openings formed in the lower surface, respectively.

In the coupling state of the duct block 333 and the packing block 334, the push end 3343 of the packing block 334 may be received by the push body receiving groove 333a, and the distal end of the push end may be in close contact with the push body 3335. Similar to the above-described embodiment, in the present embodiment, a gas communication groove 1343a (refer to FIG. 7) may be formed in the push end 3343. Accordingly, as in the above-described embodiment, the discharge port 3341 and the exhaust port 3342 may be in fluid communication with the space inside the push body receiving groove 333a through the gas communication groove 1343a (refer to FIG. 7). In addition, although not illustrated, similar to the above-described embodiment, the expansion groove EG (refer to FIG. 11) may be formed in the push body receiving groove 333a of the present embodiment. As in the above-described embodiment, the expansion groove of the push body receiving groove 333a may be a groove formed to facilitate fluid communication through the gas communication groove when the push end 3343 is maximally received in the push body receiving groove 333a.

In a state where there is no external force, the push body 3335 according to the embodiment of FIG. 14 may be in close contact with the upper surface of the push body receiving groove 333a. To this end, an elastic member 3336 that elastically supports the push body 3335 toward the packing block 334 may be arranged inside the push body receiving groove 333a. The elastic member 3336 may be disposed between the inner wall of the duct block 333 and the push body 3335, and may be provided identically or similarly to the elastic member 1336 of the above-described embodiment.

In this state, the test gas discharged through the discharge flow path 3331 is blocked by the push body 3335 and cannot be discharged to the outside, but moves through the free space of the push body receiving groove 333a or the separate circulation induction flow path 1339 (refer to FIG. 8) and can be directly exhausted to the exhaust flow path 3332.

Unlike this, when the packing block 334 or the duct block 333 is pressurized by an external force, the elastic force of the elastic member 3336 can be overcome and the packing block 334 can be accommodated to the maximum extent into the interior of the duct block 333, as illustrated in FIG. 14. In this state, the test gas discharged through the discharge flow path 3331 can sequentially pass through the expansion groove formed in the push body receiving groove 333a and the gas communication groove of the push end 3343 and finally be discharged through the discharge port 3341. Similarly, the test gas exhausted through the exhaust port 3342 can pass through the exhaust port 3342, and then sequentially pass through the gas communication groove and the expansion groove and finally be exhausted to the outside through the exhaust flow path 3332.

In this case, the external force for moving the push body 3335 may be obtained through a separate member that rises as the test tray approaches, or by a separate driving device.

Meanwhile, in the embodiment according to FIG. 14, the push body 3335 may be formed such that an alignment protruding end 3335a protrudes from a surface facing the packing block 334. The alignment protruding end 3335a may be inserted into the interior of an alignment groove 334a formed between the discharge port 3341 and the exhaust port 3342 in the packing block 334. The alignment protruding end 3335a and the alignment groove 334a may extend in a direction parallel to the relative approach direction of the test tray to the packing block 334, thereby guiding the direction of movement when the packing block 334 and the duct block 333 are in close contact with each other. Accordingly, according to one embodiment of the present disclosure, even when the packing block 334 and the duct block 333 are somewhat misaligned from the initial state due to thermal deformation, there is an effect of being able to move the packing block 334 in the correct direction relative to the duct block 333.

According to the embodiment according to FIG. 14, since the fluid movement path can be controlled for both the discharge flow path 3331 and the exhaust flow path 3332 with one push body 3335, it is particularly advantageous when the semiconductor product is small and the gap between the discharge flow path 3331 and the exhaust flow path 3332 is very narrow.

In addition, the temperature control device according to the above-described embodiments may have the following advantages. According to the temperature control device according to the present disclosure, the packing blocks 134, 234 and 334 are in close contact with each insert, so that different thermal environments can be created for each semiconductor product. Accordingly, according to the present disclosure, it is possible to have the same effect as forming an independent chamber for each semiconductor product in each insert of the test tray.

Therefore, when using the present disclosure, chambers divided into existing soak chambers, test chambers, and de-soak chambers can be integrated into one, and preheating, testing, and de-heating can be performed on each semiconductor product in a state of being seated on a tester.

A person having ordinary skill in the art to which the present disclosure pertains will understand that the present disclosure can be implemented in other specific forms without changing the technical idea or essential characteristics thereof. Therefore, it should be understood that the embodiments described above are exemplary in all respects and not restrictive. The scope of the present disclosure is indicated by the claims described below rather than the detailed description above, and all changes or modified forms derived from the meaning and scope of the claims and their equivalent concepts should be interpreted as being included in the scope of the present disclosure.

1. A temperature control system for providing a temperature control space for an individual semiconductor product in a test of a semiconductor product, the temperature control system comprising:
an insert configured to load the semiconductor product into an accommodating space with open one surface;
a test tray on which a plurality of the inserts are loaded;
a tester configured to test the semiconductor product through the insert in a state where the test tray is mounted; and
a temperature control device in close contact with one surface of the test tray or the insert in a state where the test tray is mounted on the tester and configured to separate the accommodating space from an external space and control temperature of the accommodating space.

2. The temperature control system of claim 1, wherein the temperature control device includes a packing block in close contact with the test tray or the insert and formed with a discharge port for discharging a temperature-controlled test gas into the accommodating space and an exhaust port for exhausting the test gas from the accommodating space to the outside.

3. The temperature control system of claim 2, wherein the temperature control device further includes an auxiliary fluid discharge pipe disposed to penetrate the packing block and configured to discharge an auxiliary fluid for temperature control into the accommodating space.

4. The temperature control system of claim 2, wherein the temperature control device further includes
a gas circulator configured to circulate the test gas and control temperature, and
a duct block configured to distribute and deliver the test gas delivered from the gas circulator to a plurality of the packing blocks and deliver the test gas exhausted through the plurality of the packing blocks to the gas circulator.

5. The temperature control system of claim 4, wherein the temperature control device further includes a temperature measurement sensor built into the packing block or the duct block to measure temperature.

6. The temperature control system of claim 4, wherein the temperature control device further includes a distribution plate that forms a circulation path of the test gas between the plurality of duct blocks and the gas circulator.

7. The temperature control system of claim 6, wherein one surface of the distribution plate facing the test tray is formed to have an extent corresponding to the test tray, and
each of the duct blocks is disposed on one surface of the distribution plate to correspond to a different area of the test tray.

8. The temperature control system of claim 7, wherein the temperature control device further includes a heat exchange unit disposed in the duct block and configured to control the temperature of the test gas distributed to the plurality of packing blocks.

9. The temperature control system of claim 4, wherein the temperature control device further includes a circulation chamber in which the gas circulator is disposed and which provides a space in which the test gas is circulated, so that the test gas waits in a temperature-controlled state.

10. The temperature control system of claim 9, wherein the temperature control device further includes a dry chamber that the circulation chamber is disposed inside and which maintains temperature of an internal space within a predetermined range.

11. The temperature control system of claim 9, wherein the temperature control device further includes a dry chamber that the circulation chamber is disposed inside and that humidity of an internal space is controlled.

12. The temperature control system of claim 4, wherein the duct block includes
a discharge flow path extending straightly toward the packing block and communicating with the discharge port, and
an exhaust flow path communicating with the exhaust port and bent at least once inside the duct block.

13. The temperature control system of claim 2, wherein the discharge port and the exhaust port are formed to be positioned on a central axis of an upper surface of the accommodating space.

14. The temperature control system of claim 1, wherein the temperature control device further includes a packing member configured to seal a gap between the packing block and the insert in a state where the packing block is in close contact with the test tray or the insert.

15. A temperature control device providing a temperature control space for a semiconductor product, which approaches an insert for loading a semiconductor product into an accommodating space with open one surface and separates the accommodating space from an external space, the temperature control device comprising:
a packing block that is in close contact with a test tray on which the insert is loaded or the insert, and has a discharge port for discharging a temperature-controlled test gas into the accommodating space and an exhaust port for exhausting the test gas from the accommodating space to an outside.
